(19) United States
(12) Patent Application Publication
(10) Pub. No.: US 2024/0035194 A1
(43) Pub. Date: Feb. 1, 2024

(54) Method for growing halide perovskite nanocrystals through in-situ chemical vapor deposition

(71) Applicant: Wenzhou Xinxin Taijing Technology Co., Ltd., Wenzhou City (CN)

(72) Inventors: Chao Fan, Wenzhou City (CN); Xingliang Dai, Wenzhou City (CN); Haiping He, Wenzhou City (CN)

(21) Appl. No.: 18/205,532

(22) Filed: Jun. 3, 2023

(30) Foreign Application Priority Data
Aug. 1, 2022 (CN) 202210919904.9

(51) Int. Cl. C30B 25/16; C30B 29/12

(52) U.S. Cl. CPC C30B 25/16; C30B 29/12

(57) ABSTRACT

A method for growing halide perovskite nanocrystals through in-situ chemical vapor deposition comprises the steps: grinding and mixing lead halide powder and cesium halide powder to obtain a solid-phase precursor; mixing the solid-phase precursor with the mesoporous molecular sieve; heating the mixed powder in a nitrogen atmosphere, such that the solid-phase precursor is sublimated into a gaseous state and is adsorbed into the pore channels of the mesoporous molecular sieve; and lowering the temperature, such that the gas-phase lead, the cesium, and the halogen atom react in-situ in the pore channels of the molecular sieve to form the halide perovskite nanocrystal. The fluorescence quantum yield of the CsPbBr₃ nanocrystal is improved to 90% or higher by passivating its surface defects with Cs₄PbBr₆, thereby enhancing its luminescence properties. Meanwhile, halide perovskite nanocrystals with different luminescence colors are obtained by adjusting the types of halogen in lead halide and cesium halide.

### CROSS-REFERENCE TO RELATED APPLICATIONS

The present application claims the priority of Chinese Patent Application No. 202210919904.9, filed on Aug. 1, 2022, the contents of which are incorporated herein in their entirety by reference.

### TECHNICAL FIELD

The present invention relates to the technical field of preparation of halide perovskite nanocrystals, and in particular, to a method for growing a halide perovskite nanocrystal through in-situ chemical vapor deposition.

### BACKGROUND ART

Halide perovskite nanocrystals have excellent optical characteristics such as a high fluorescence quantum yield, a narrow emission half-peak width, and a continuously tunable light emission wavelength, which makes the halide perovskite nanocrystals become a focus of interest in scientific research and industry, and is one of the best candidates for the next generation of luminescent materials. However, since the halide perovskite is an ionic compound with soft lattice characteristics, it is susceptible to ion migration, phase transition, and decomposition in high humidity, high temperature, and ultraviolet irradiation environments, which greatly affects its stability. Therefore, preparing a halide perovskite nanocrystal structure with high stability has important practical significance for promoting the commercial application of perovskite materials.

The surface coating structure effectively isolates perovskite nanocrystals from the external environment, such that the stability of the perovskite against moisture, oxygen, heat, and light irradiation can be greatly improved. At present, direct growth of perovskite nanocrystals in the microporous channel of an inorganic porous material (for example, mesoporous silica, molecular sieve, zeolite, and the like) can effectively form the surface coating structure, thereby improving the stability of perovskite.

However, there are some key problems yet to be solved in the art of direct growth of perovskite nanocrystals in pores of a porous material. First, the current technology primarily concentrates on the green light-emitting CsPbBr₃ nanocrystals, lacking attention to the red light-emitting CsPbI₃ nanocrystals and blue light-emitting CsPbClₓBr₃, nanocrystals. Second, the common method of preparing perovskite nanocrystals in porous materials involves soaking the porous inorganic material in a liquid-phase precursor solution, which fills its pores with precursor ions. This method limits preparation efficiency and generates waste liquid, causing an increase in preparation costs. Third, the CsPbBr₃ nanocrystals that are directly grown in the pores of the porous material lack a surface defect passivation mechanism, hindering the further improvement of their luminescence properties.

Therefore, there is a need to improve conventional technology.

### SUMMARY OF THE INVENTION

An object of the present invention is to provide a method for growing halide perovskite nanocrystals through in-situ chemical vapor deposition, to solve the problems outlined in the above background art.

To attain the above object, the present invention provides the following technical solution: a method for growing a halide perovskite nanocrystal through in-situ chemical vapor deposition, comprising preparing a solid-phase precursor, and preparing a halide perovskite nanocrystal.

Further, the steps involved in the preparation of the solid-phase precursor are detailed below:

grinding and mixing cesium bromide and lead bromide powder to obtain a solid-phase precursor for preparing CsPbBr₃ nanocrystal; and/or grinding and mixing cesium bromide, lead bromide, cesium chloride, and lead chloride powder to obtain a solid-phase precursor for preparing CsPbClₓBr₃₋ₓ mixed halogen nanocrystal; and/or grinding and mixing cesium iodide and lead iodide powder to obtain a solid-phase precursor for preparing CsPbI₃ nanocrystal.

Further, the specific steps for preparing the halide perovskite nanocrystal are as follows:

grinding and mixing the solid-phase precursor and MCM-41 mesoporous molecular sieve; and then, heating the mixed powder in a nitrogen atmosphere and maintaining for 30-90 minutes, such that the solid-phase precursor is sublimated into a gaseous state and adsorbed into the pore channels of the mesoporous molecular sieve; and then, lowering the temperature with a cooling rate maintained at 3-10° C./min, such that the gas phase lead, cesium, and halogen atoms react in-situ in the pore channels of the molecular sieve and form the halide perovskite nanocrystal.

Compared with the prior art, the present invention has the following beneficial effects.

The present invention provides an all-solid-state precursor method for preparing halide perovskite nanocrystals, which eliminates the waste liquid generated by conventional liquid-phase precursor methods. The present invention greatly improves the luminescence properties of CsPbBr₃ nanocrystals by passivating its surface defects with Cs₄PbBr₆ through the in-situ growth of Cs₄PbBr₆ and CsPbBr₃ mixed phase within the pore channels of a molecular sieve. This leads to a fluorescent quantum yield of 90% or higher for the CsPbBr₃ nanocrystals. By adjusting the halogen types in lead halide and cesium halide, it's possible to grow halide perovskite nanocrystals with different luminescence colors in the pore channels of molecular sieves. These include green light CsPbBr₃ nanocrystals, blue light CsPbClₓBr₃₋ₓ nanocrystals, and red light CsPbl₃ nanocrystals, which expands the optical application range for the technology of growing halide perovskite nanocrystals in molecular sieves.

### BRIEF DESCRIPTION OF THE DRAWINGS

FIG. 1 is the flow chart of an embodiment of the method for growing a halide perovskite nanocrystal through in-situ chemical vapor deposition according to the present invention.

FIG. 2 is the X-ray diffraction patterns of nanocrystals prepared from precursors with different CsBr:PbBr₂ ratios according to an embodiment of the present invention.

FIG. 3 is the light absorption spectrum and the fluorescence emission spectrum of nanocrystals prepared from precursors with different CsBr:PbBr₂ ratios according to an embodiment of the present invention.

FIG. 4 is the fluorescence quantum yield diagrams of nanocrystals prepared from precursors with different CsBr:PbBr₂ ratios according to an embodiment of the present invention.

FIG. 5 is the fluorescence emission spectrum of nanocrystals prepared from precursors with different CsBr:PbBr₂:CsCl:PbCl₂ ratios according to an embodiment of the present invention.

FIG. 6 is the fluorescence emission spectrum of the CsPbI₃ nanocrystals according to an embodiment of the present invention.

### DETAILED DESCRIPTION OF THE PREFERRED EMBODIMENTS

The present disclosure will be further described below with reference to specific embodiments, and it should be noted that, without conflict, any combination of the embodiments or the technical features described below may form a new embodiment.

According to an embodiment of the present invention, a method for growing a halide perovskite nanocrystal through in-situ chemical vapor deposition is provided, and for a CsPbBr₃ nanocrystal with green light emission, the specific experimental steps are as follows:

1. Grinding and mixing cesium bromide and lead bromide powders with the molar ratio of cesium bromide to lead bromide of 1:1, 1.5:1, and 2:1 to obtain three solid-phase precursors with different molar ratios.

2. Grinding and mixing the three solid-phase precursors and MCM-41 mesoporous molecular sieve with a mass ratio of 13:10; and then, heating the mixed powder in a nitrogen atmosphere, with temperature increase from room temperature to 565° C. and continuously heating at 565° C. for 40 minutes, the solid-phase precursor sublimates to a gaseous state and is adsorbed into the pore channels of the MCM-41 mesoporous molecular sieve; and then, lowering the temperature to room temperature, with a cooling rate maintained at 5° C./min, such that CsPbBr₃ nanocrystals are formed through the in-situ reaction of bromine, lead and cesium atoms in the gas phase in the pore channels of MCM-41 molecular sieve during the cooling process.

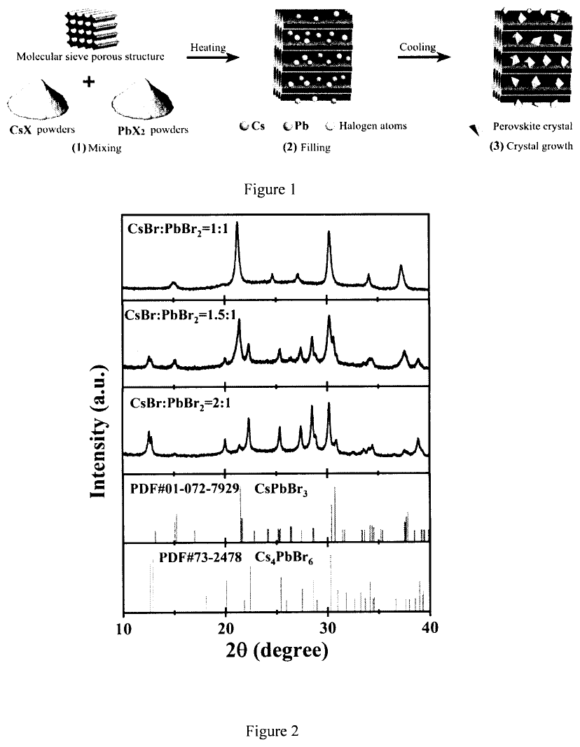

Experimental analysis: The nanocrystal samples prepared from the three solid-phase precursors with different molar ratios were tested with X-ray diffraction. The detailed patterns are shown in FIG. 2. Only the CsPbBr₃ phase existed in the nanocrystal prepared from the solid-phase precursor with the molar ratio of cesium bromide to lead bromide of 1:1. As the cesium bromide in the precursor increased, there is not only the CsPbBr₃ phase in the nanocrystal, and the component of the Cs₄PbBr₆ phase gradually increased.

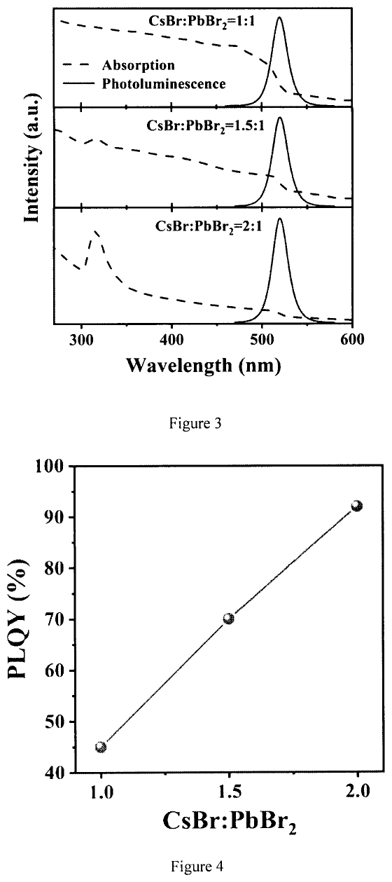

The nanocrystal samples prepared from the three solid-phase precursors with different molar ratios were tested with the light absorption spectrum and the fluorescence emission spectrum. The detailed spectra are shown in FIG. 3. The three nanocrystal samples all show green-light fluorescence emission with a peak position of 520 nm, corresponding to the exciton radiation recombination of CsPbBr₃. As the cesium bromide in the solid-phase precursor increased, the absorption spectrum of the nanocrystal as prepared enhanced at an absorption peak of 317 nm, corresponding to the absorption peak of Cs₄PbBr₆. It is proved that the component of the Cs₄PbBr₆ phase gradually increased and verified the results obtained from XRD diffraction analysis as above.

The fluorescence quantum yield of the nanocrystals prepared from solid-phase precursors with different molar ratios was tested and detailed spectra are shown in FIG. 4. Results show that as the amount of Cs₄PbBr₆ phase in the nanocrystal increases, the green light fluorescence quantum yield of the nanocrystal gradually increases and can reach a maximum of 92%. This demonstrates that the formation of the Cs₄PbBr₆ phase can effectively passivate surface defects of CsPbBr₃, reduce non-radiative recombination, and thus enhance the luminescence properties of CsPbBr₃ nanocrystals.

According to an embodiment of the present invention, it is provided a method for growing a halide perovskite nanocrystal through in-situ chemical vapor deposition, and for a CsPbClₓBr₃₋ₓ mixed halogen nanocrystal with blue light emission, the specific experimental steps are as follows:

1. Grinding and mixing cesium bromide, lead bromide, cesium chloride, and lead chloride powders with the molar ratio of 2:2:1:1, 2:1:1:0.5, and 2:0.6:1:0.3 to obtain three solid-phase precursors with different molar ratios.

2. Grinding and mixing the three solid-phase precursors and MCM-41 mesoporous molecular sieve with a mass ratio of 13:10; and then, heating the mixed powder in a nitrogen atmosphere, with temperature increase from room temperature to 575° C. and continuously heating at 575° C. for 40 minutes, the solid phase precursor sublimates to a gaseous state and is adsorbed into the pore channels of the MCM-41 mesoporous molecular sieve.; and then, lowering the temperature to room temperature, with a cooling rate maintained at 5° C./min, such that CsPbClₓBr₃₋ₓ mixed halogen nanocrystals are formed through the in-situ reaction of bromine, lead and cesium atoms in the gas phase within the pore channels of the MCM-41 molecular sieve during the cooling process.

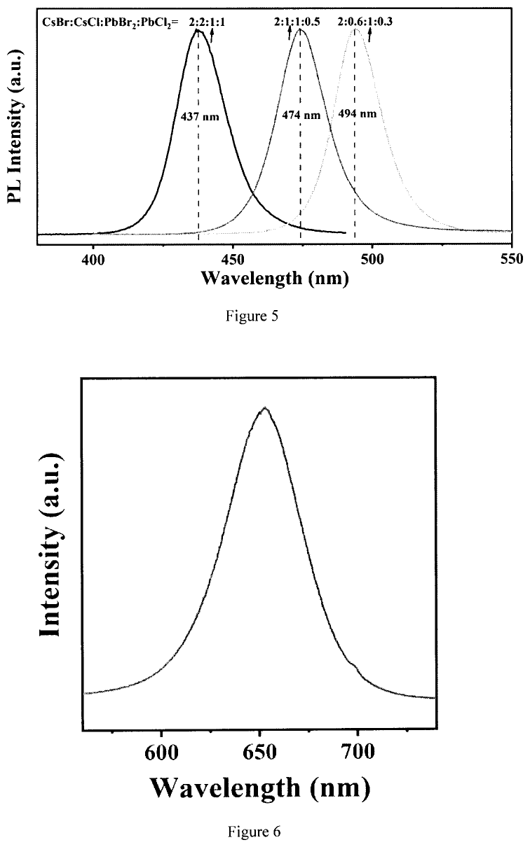

Experimental analysis: The nanocrystal samples prepared from the three solid-phase precursors with different molar ratios were tested with the fluorescence emission spectrum. The detailed spectra are shown in FIG. 5. As the Cl component increased, the luminescence peak gradually shifted from the blue light at 484 nm to the sky blue light at 474 nm and the dark blue light at 437 nm. It is proved that the method of the present invention can control the luminescence color of the product nanocrystal by adjusting the halogen component in the precursor to obtain the blue light nanocrystal.

According to an embodiment of the present invention, it is provided a method for growing a halide perovskite nanocrystal through in-situ chemical vapor deposition, and for a CsPbI₃ nanocrystal with red light emission, the specific experimental steps are as follows:

1. Grinding and mixing cesium iodide and lead iodide at a molar ratio of 1:1 to obtain a solid-phase precursor.

2. Grinding and mixing the solid-phase precursor and MCM-41 mesoporous molecular sieve with a mass ratio of 13:10; and then, heating the mixed powder in a nitrogen atmosphere, with temperature increase from room temperature to 450° C. and continuously heating at 450° C. for 60 minutes; and then, lowering the temperature to room temperature, with a cooling rate maintained at 5° C./min, such that CsPbI₃ nanocrystals are formed in the pore channels of the MCM-41 molecular sieve during the cooling process.

Experimental analysis: The nanocrystal samples prepared from the solid-phase precursor were tested with the fluorescence emission spectrum. The detailed spectra are shown in FIG. 6. It showed 650 nm red fluorescence emission, corresponding to the exciton radiation recombination of CsPbI₃. It is proved that the method of the present invention is also suitable for preparing the CsPbI₃ nanocrystal with red light emission.

The basic principles, main features, and advantages of the present application are described above. It should be understood by those skilled in the art that the present application is not limited by the foregoing embodiments, and the embodiments and the description described above are merely the principles of the present application, and various changes and improvements will also be provided in the present application without departing from the spirit and scope of the present application, and these changes and improvements fall within the scope of the present application that is claimed. The scope of protection of the present application is defined by the appended claims and their equivalents.

1. A method for growing a halide perovskite nanocrystal through in-situ chemical vapor deposition, comprising the following steps: grinding and mixing lead halide powder and cesium halide powder to obtain a solid-phase precursor; mixing the solid-phase precursor with MCM-41 mesoporous molecular sieve with a mass ratio of 13:10; and then, heating the mixed powder in a nitrogen atmosphere, with a temperature increase from room temperature to a first temperature condition or a second temperature condition, and continuously heating for 30-90 minutes at the first temperature condition or the second temperature condition; and then lowering the temperature to room temperature, with a cooling rate maintained at 3-10° C./min.

2. The method for growing a halide perovskite nanocrystal through in-situ chemical vapor deposition according to claim 1, wherein the preparing the solid-phase precursor comprises the following specific steps: grinding and mixing cesium bromide and lead bromide powder with the molar ratio of 1:1 to 2:1 to obtain a solid-phase precursor for preparing CsPbBr₃ nanocrystal.

3. The method for growing a halide perovskite nanocrystal through in-situ chemical vapor deposition according to claim 1, wherein the preparing the solid-phase precursor comprises the following specific steps; grinding and mixing cesium bromide, lead bromide, cesium chloride, and lead chloride powder to obtain a solid-phase precursor for preparing CsPbClₓBr₃, nanocrystal, wherein the molar ratio of cesium bromide to lead bromide is 2:2 to 2:0.6; the molar ratio of lead bromide to cesium chloride is 2:1 to 0.6:1; the molar ratio of cesium chloride to lead chloride is 1:1 to 1:0.3.

4. The method for growing a halide perovskite nanocrystal through in-situ chemical vapor deposition according to claim 1, wherein the preparing the solid-phase precursor comprises the following specific steps; grinding and mixing cesium iodide and lead iodide powder with the molar ratio of 1:1 to obtain a solid-phase precursor corresponding to CsPbI₃ nanocrystal.

5. The method for growing a halide perovskite nanocrystal through in-situ chemical vapor deposition according to claim 2, wherein the first temperature condition of 560-590° C. is used for the preparation of the CsPbBr₃ nanocrystal.

6. The method for growing a halide perovskite nanocrystal through in-situ chemical vapor deposition according to claim 3, wherein the first temperature condition of 560-590° C. is used for the preparation of the CsPbClₓBr₃₋ₓ nanocrystal.

7. The method for growing a halide perovskite nanocrystal through in-situ chemical vapor deposition according to claim 4, wherein the second temperature condition of 350-550° C. is used for the preparation of the CsPbI₃ nanocrystal.
